(19) United States
(12) Patent Application Publication
(10) Pub. No.: US 2004/0206300 A1
(43) Pub. Date: Oct. 21, 2004

(54) Method for forming thin films with lateral composition modulations

(76) Inventor: Victor B. Sapozhnikov, Minnetonka, MN (US)

Correspondence Address: KINNEY & LANGE, P.A., THE KINNEY & LANGE BUILDING, 312 SOUTH THIRD STREET, MINNEAPOLIS, MN, 55415-1002, US

(21) Appl. No.: 10/842,919

(22) Filed: May 11, 2004

Related U.S. Application Data
(62) Division of application No. 09/619,738, filed on Jul. 19, 2000, now abandoned.
(60) Provisional application No. 60/146,229, filed on Jul. 28, 1999.

(51) Int. Cl. C23C 16/00; C23C 14/00; C30B 23/00; C30B 25/00; C30B 28/12; C30B 28/14; C25B 9/00; C25B 11/00; C25B 13/00

(52) U.S. Cl. 117/84

(57) ABSTRACT

A thin film structure is formed by simultaneously depositing at least two components onto a substantially planar substrate. Each component is deposited from a deposition direction different than the deposition directions from which the remaining components are deposited. The deposition directions are measured in a plane of the thin film structure. Each component is further deposited at a deposition angle which is measured with respect to a line perpendicular to the plane of the thin film structure. The deposition angles and deposition directions of the at least two components are oriented to cause the thin film structure to have atomic-scale lateral composition modulations.

### CROSS-REFERENCE TO RELATED APPLICATION(S)

This Application is a divisional of application Ser. No. 09/619,738, filed on Jul. 19, 2000 entitled “Thin Films with Lateral Composition Modulations”, which claims priority from provisional patent application No. 60/146,229, filed Jul. 28, 1999 for “Thin Films With Lateral Anisotropic Composition Variations At Atomic Scales” of Victor B. Sapozhnikov.

### BACKGROUND OF THE INVENTION

The present invention relates generally to the field of thin films. In particular, the present invention relates to a method for forming a thin film structure with lateral composition modulations at atomic scales.

Thin film structures are widely used in the fields of microelectronics and magnetic data storage and retrieval systems. To impart useful properties onto these thin film structures, the composition of the thin film is commonly varied, or modulated, at atomic scales throughout the structure. Generally, this composition modulation occurs along a vertical axis of the film. Such vertical composition modulations are created by forming the thin film structure of several thin layers of varying compositions, each layer being only a few Angstroms thick. The resultant thin film structure will have a composition which varies in the direction normal to the plane of each of the layers.

Less common is a thin film structure having lateral composition modulations; that is, a composition which varies within the plane of the thin film structure itself. Although a multitude of useful applications exist for such thin film structures, the difficulty in consistently producing such structures has generally precluded their use. Notably, convention shaping methods, such as photolithography, have tolerances which are too great to allow for the controlled creation of a thin film structure having lateral composition modulations at atomic scales. Importantly, a thin film structure having lateral composition modulations would likely have useful anisotropic properties.

Recent years have seen the development of spontaneously-formed structures having lateral composition modulations of certain semiconductor materials. In these spontaneously-formed structures, the lateral composition modulations are coupled to surface morphology in molecular beam epitaxy (MBE) grown short-period superlattices of III-V alloys.

There has also been development in the area of spontaneously-formed giant magnetoresistive multi-layer structures formed of alternating stripes of ferromagnetic and nonferromagnetic metal that are stacked laterally on a special template layer. The template layer is a crystalline structure that has a two-fold uniaxial surface about an axis perpendicular to the surface plane. The alternating stripes of ferromagnetic and nonferromagnetic metal become spontaneously arranged laterally on the template layer during co-deposition.

Such “self-assembled” structures, however, are limited in application to specific materials having the proper crystal structure to spontaneously arrange themselves, or those formed on a specific substrate having the proper crystal structure to cause lateral composition modulations.

Thus, there is a need for a thin film structure having lateral composition variation without the need for “self-assembly”.

### BRIEF SUMMARY OF THE INVENTION

A thin film structure is formed by simultaneously depositing at least two components onto a substantially planar substrate. Each component is deposited from a deposition direction different than the deposition directions from which the remaining components are deposited. The deposition directions are measured in a plane of the thin film structure. Each component is further deposited at a deposition angle which is measured with respect to a line perpendicular to the plane of the thin film structure. The deposition angles and deposition directions of the at least two components are oriented to cause the thin film structure to have atomic-scale lateral composition modulations.

### BRIEF DESCRIPTION OF THE DRAWINGS

FIGS. 1A, 1B, 1C and 1D are top views of a computer simulated thin film structure in accord with the present invention at four distinct intervals during the structure's formation.

FIGS. 2A, 2B, 2C and 2D are side views of the computer simulated thin film structures of respective FIGS. 1A, 1B, 1C and 1D.

FIG. 3 is a graph displaying correlation functions C_{AB}(x) and C_{AB}(y), as well as correlation anisotropy C_{AB}(x)-C_{AB}(y), for a first layer of twenty layers of the thin film structure of FIGS. 1 and 2.

FIG. 4 is a graph displaying correlation functions C_{AB}(x) and C_{AB}(y), as well as correlation anisotropy C_{AB}(x)-C_{AB}(y), for a fifteenth layer of twenty layers of the thin film structure of FIGS. 1 and 2.

FIGS. 5A, 5B, 5C and 5D are top views of a computer simulated thin film structure in accord with the present invention at four distinct intervals during the structure's formation.

FIGS. 6A, 6B, 6C and 6D are side views of the computer simulated thin film structure of respective FIGS. 5A, 5B, 5C and 5D.

### DETAILED DESCRIPTION

The present invention is an anisotropic thin film structure having lateral composition modulations which cause the thin film structure to exhibit anisotropic properties. Such a thin film structure can be built by depositing at least two separate components at differing deposition angles, deposition directions and/or deposition rates.

These composition variations, or modulations, result from a natural roughness of a growing film surface. During deposition of a thin film structure, a top surface of the structure will not grow evenly; that is, mounds and valleys in the top surface will form. Thus, if two distinct components A and B were simultaneously deposited at respective opposing directions east and west, then an eastern side of the mounds would tend to collect more atoms of component A than atoms of component B. Similarly, a western side of the mounds would tend to collect more atoms of component B than atoms of component A. Thus, a ballistic separation of components A and B takes place, a signature of which is created in a growing surface morphology of the thin film structure's composition.

A thin film structure grown in this fashion will have a lateral composition modulation at atomic scales, and an anisotropy in the film's composition since a “north-south” path through the thin film structure will have a composition different than an “east-west” path through the thin film structure. In creating such an anisotropic thin film structure, several other parameters, such as deposition rate, deposition angle, deposition direction and temperature, will have an effect on the composition of the final thin film structure. Of course, more than two components and two deposition directions can be used.

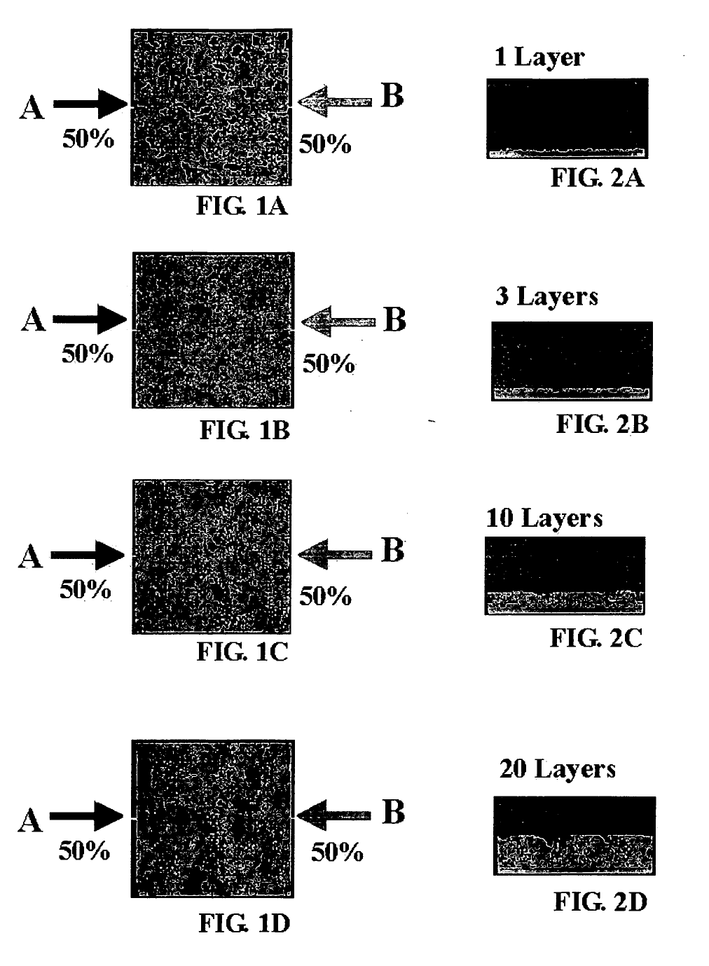

FIGS. 1A, 1B, 1C and 1D are top views of a computer simulated thin film structure in accord with the present invention at four distinct intervals during the structure's formation. FIGS. 2A, 2B, 2C and 2D are side views of the computer simulated thin film structures of respective FIGS. 1A, 1B, 1C and 1D. The thin film structure evolves from only 1 atomic layer in FIGS. 1A and 2A, to 3 atomic layers in FIGS. 1B and 2B, to 10 atomic layers in FIGS. 1C and 2C and finally to 20 atomic layers in FIGS. 1D and 2D.

In this example, the thin film structure is formed by simultaneously sputter-depositing a component A and a component B onto a substrate from opposing directions at equal deposition rates. Component A is deposited at a deposition angle of −80° with respect to vertical (e.g., normal to the deposition surface) while component B is deposited at a deposition angle of 80° with respect to vertical. Component A is illustrated as being a shade lighter than the substrate, while component B is illustrated as being a shade lighter than component A.

After a single atomic layer has been deposited, portions of the substrate are left uncovered by components A and B. (FIGS. 1A and 2A). Once the thin film structure is built up to three atomic layers, an unevenness of a top surface of the thin film structure has grown more pronounced as mounds and valleys in the top surface begin taking shape and cause the ballistic separation of components A and B. (FIGS. 1B and 2B). As the thin film structure is continued to be built, atoms of components A and B will tend to collect on opposite sides of the mounds, thereby resulting in a lateral composition modulation in the thin film structure. Once the thin film structure is built up to ten atomic layers, the ballistic separation of components A and B is well defined. (FIGS. 1C and 2C). Finally, when the thin film structure has been built up to twenty atomic layers, the anisotropy of the thin film structure's composition is clearly visible as substantially lateral stripes of components A and B are formed in a direction substantially normal to the direction at which components A and B are deposited. (FIGS. 1D and 2D).

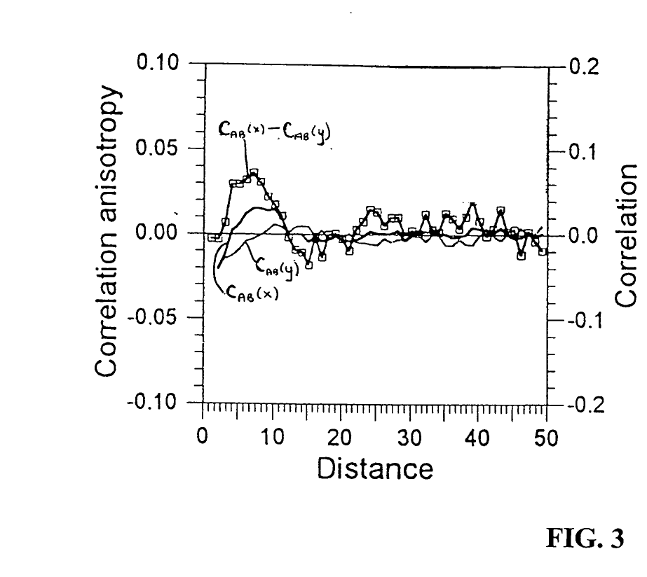

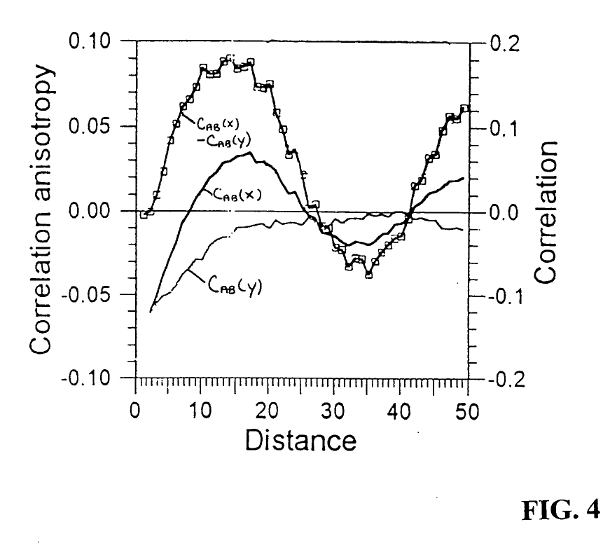

FIG. 3 is a graph displaying pair correlation functions C_{AB}(x) and C_{AB}(y), as well as correlation anisotropy C_{AB}(x)-C_{AB}(y), for a first of twenty layers of the thin film structure of FIGS. 1D and 2D. FIG. 4 is a similar graph for a fifteenth of twenty layers of the thin film structure of FIGS. 1D and 2D.

One-dimensional pair correlation function C_{AB}(x) is computed by subtracting the concentration of component B atoms from the probability of finding an atom of component B at a specific distance in the x-direction (the direction of deposition) from an atom of component A. Similarly, one-dimensional pair correlation function C_{AB}(y) is computed by subtracting the concentration of component B atoms from the probability of finding an atom of component B at a specific distance in the y-direction (normal to the direction of deposition) from an atom of component A.

FIGS. 3 and 4 quantify the anisotropic variation in the thin film structure's composition. The anisotropy of the thin film structure can be evaluated by comparing the correlation functions in the x- and y-directions. In FIG. 3, each of the one-dimensional correlation functions C_{AB}(x) and C_{AB}(y) deviates only a small amount from zero, especially at larger distances. The curves in FIG. 3 indicate that some lateral composition modulation occurs at this first layer, but very little. Accordingly, correlation anisotropy C_{AB}(x)-C_{AB}(y) also deviates very little from zero.

In FIG. 4, a much more pronounced correlation is visible. The one-dimensional correlation functions C_{AB}(x) and C_{AB}(y) differ substantially from one another. At small distances, correlation function C_{AB}(y) is large for only small distances, and approaches zero for larger distances. This curve illustrates that lateral stripes of components A and B have formed at the fifteenth atomic layer. Correlation function C_{AB}(x), on the other hand, is periodic, illustrating that lateral stripes exist at the fifteenth atomic layer. Correlation function C_{AB}(x)-C_{AB}(y) is a large periodic curve which illustrates the substantial differences between correlation functions C_{AB}(x) and C_{AB}(y).

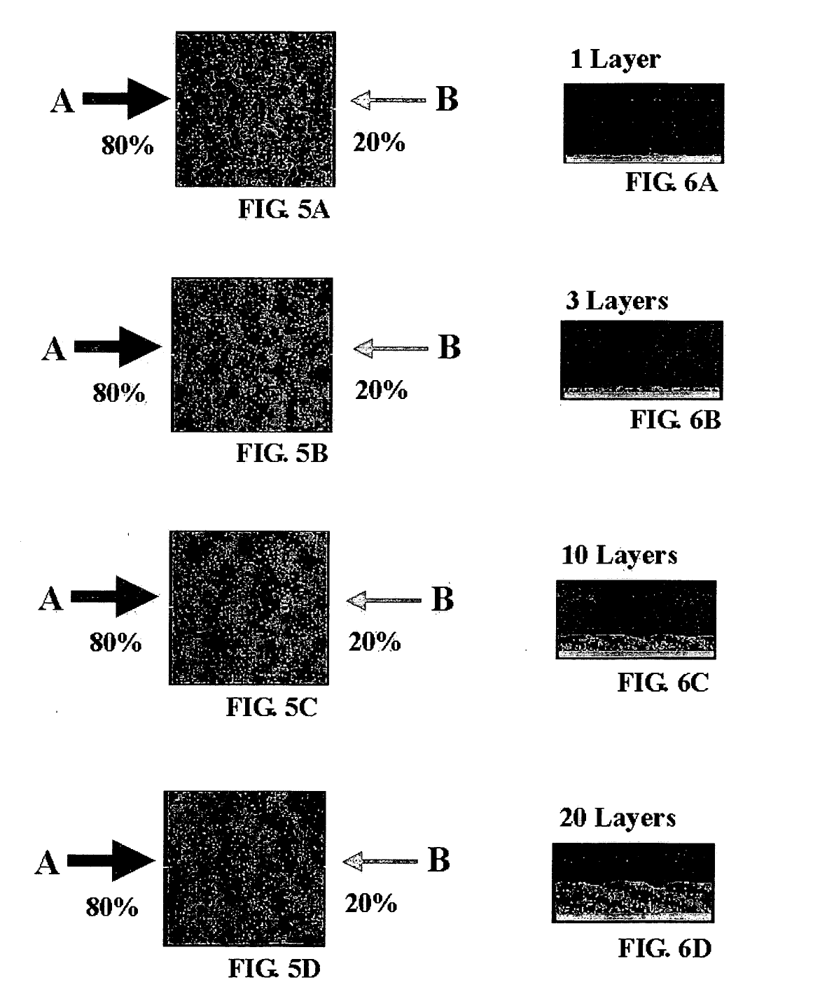

FIGS. 5A, 5B, 5C and 5D are top views of a computer simulated thin film structure in accord with the present invention at four distinct intervals during the structure's formation. FIGS. 6A, 6B, 6C and 6D are side views of the computer simulated thin film structures of respective FIGS. 5A, 5B, 5C and 5D. The thin film structure evolves from only 1 atomic layer in FIGS. 5A and 6A, to 3 atomic layers in FIGS. 5B and 6B, to 10 atomic layers in FIGS. 5C and 6C and finally to 20 atomic layers in FIGS. 5D and 6D.

In this example, the thin film structure is formed by simultaneously sputter-depositing a component A and a component B onto a substrate from opposing directions at unequal deposition rates and at respective deposition angles of −80′ and 80° with respect to vertical. Component A is deposited at 0.8 atomic layers per second, while component B is deposited at 0.2 atomic layers per second. Component A is deposited at Component A is illustrated as being a shade lighter than the substrate, while component B is illustrated as being a shade lighter than component A.

These varied deposition rates create an additional effect on the composition of the thin film structure. In addition to the anisotropic composition modulations in each atomic plane, anisotropic correlation occurs in a plane normal to each of the direction of deposition and to the atomic planes. Indeed, because the deposition rates are different, the mounds drift toward the faster-deposition direction as the film grows. This makes the concentration variations lean toward that direction. This effect is most evident in FIGS. 6C and 6D. This effect can be used as another leverage to control magnetic and transport properties of such modulated films.

In generating a thin film structure in accord with the present invention, any or all of the following variables can be varied: number of components, deposition direction of each component, deposition angle of each component, deposition rate of each component, and temperature at which the components are deposited. As shown above, varying the deposition rates can impart composition anisotropy in a vertical plane, as well as a lateral plane.

A thin film structure in accord with the present invention is formed of at least two components. To maximize anisotropy in a lateral plane of the structure, the number of components preferably equals two.

The at least two components are preferably deposited at deposition directions such that an angle formed between deposition directions is greater than zero. More preferably, the angle formed between deposition directions is between about 90° and about 180°. For instance, for a three component thin film structure, the components could be deposited at 0°, 120° and 240°, such that the deposition direction of each component is separated by 120°. Alternatively, the three components could be deposited at 0°, 180° and 270°, or any other combination of angles. For a two component system, the angle between the two deposition directions is preferably equal to about 180°, such that the deposition directions of the two components are substantially opposite one another. In a two component system, as the angle is decreased from 180°, the separation of components (which results in the thin film structure exhibiting lateral composition anisotropy) will be less pronounced.

Also preferred is that the at least two components be deposited at a deposition angle, which is measured with respect to vertical, greater than zero. More preferably, the deposition angle is between about ±60° and about ±90°, and most preferably, as close to ±90° as possible. The angle of the at least two components can vary from one another, or can be equal to one another.

Because temperature at which the components are deposited affects the roughness of a growing thin film structure's top surface, temperature will affect the thin film structure's composition variations. Of interest, as the deposition angle is increased toward ±90°, the surface need be less rough to achieve a well-defined separation between the components in the thin film structure. Conversely, as the angle is decreased from ±90°, the surface needs to be rougher to still allow for well-defined component separation.

In summary, to best achieve lateral composition anisotropy in a thin film structure, it is preferred that two components be deposited from opposite deposition directions (that is, 180° between them), with a deposition angle as close to ±90° as possible. In such a system, as the deposition angle is increased toward ±90°, the angle formed between the deposition directions can stray from +180° to achieve similar results. Conversely, as the angle formed between deposition directions is increased to 180°, the deposition angle can be reduced.

Imparting atomic-scale lateral composition modulations into a thin film structure may result in novel materials having unusual magnetic transport and crystallographic properties. Several useful applications for such thin film structures having lateral composition modulations exist. For instance, novel thin film structures having lateral pair ordering anisotropy can be created from combinations of nickel and iron, or from cobalt and platinum, or from cobalt and palladium, or from combinations of rare earth and ferromagnetic materials. Such structures likely have a lateral magnetic anisotropy. Also, novel thin film structures can be composed of combinations of ferromagnetic and paramagnetic materials, or from ferromagnetic and diamagnetic materials. Such thin film structures can have potentially interesting magneto-transport properties. Another interesting application creates laterally layered structures for use as a magnetic core of a write head. A laterally layered magnetic core has ability to suppress harmful eddy currents in the write head. Also, novel thin film structures can be created with alternating conductor and insulating stripes. Such thin film structures have a conductivity in the x-direction substantially different from its conductivity in the y-direction. There may be many other applications.

In conclusion, the present invention is a thin film structure having lateral composition modulations. The thin film structure of the present invention is created by depositing at least two separate components at differing deposition directions, deposition angles, deposition rates and/or temperature.

Although the present invention has been described with reference to preferred embodiments, workers skilled in the art will recognize that changes may be made in form and detail without departing from the spirit and scope of the invention.

1. A method for growing a thin film structure upon a substantially planar substrate, the method comprising:
depositing a first component from a first deposition direction at a first deposition angle; and
simultaneously depositing a second component from a second deposition direction substantially opposite the first deposition direction at a second deposition angle, wherein the first and second deposition directions are measured in a plane of the thin film structure and the first and second deposition angles are measured with respect to a line perpendicular to the plane of the thin film structure.

2. The method of claim 1 and further comprising:
orienting the first and second deposition angles to impart lateral composition modulations in the thin film structure.

3. The method of claim 2 wherein the lateral composition modulations in the thin film structure are periodic.

4. The method of claim 1 and further comprising:
orienting the first and second deposition angles to cause a top surface of the thin film structure as it is grown to have an uneven film topography comprising mounds and valleys, wherein opposing sides of the mounds each tend to collect more atoms of one of the first and second components than the other of the first and second components during simultaneous deposition of the first and second components.

5. The method of claim 1 wherein the first and second deposition angles are each in a range of about 60° to about 90°.

6. The method of claim 1 wherein the first and second deposition angles are each in a range of about 75° to about 90°.

7. The method of claim 1 wherein a sum of the first and second deposition angles is in a range of about 90° to about 180°.

8. The method of claim 1 wherein a sum of the first and second deposition angles is in a range of about 120° to about 180°.

9. The method of claim 1 wherein a deposition rate of the first component is substantially equal to a deposition rate of the second component.

10. The method of claim 1 wherein a deposition rate of the first component does not equal a deposition rate of the second component.

11. The method of claim 1 wherein the first and second components are characterized by an inability to spontaneously self-assemble with each other.

12. A method for forming a thin film structure, the method comprising:
simultaneously depositing at least two components onto a substantially planar substrate, each component being deposited from a deposition direction different than the deposition directions from which the remaining components are deposited, wherein the deposition directions are measured in a plane of the thin film structure, each component further being deposited at a deposition angle which is measured with respect to a line perpendicular to the plane of the thin film structure; and
orienting the deposition angles and deposition directions of the at least two components to cause the thin film structure to have atomic-scale lateral composition modulations.

13. The method of claim 12 wherein the deposition angles of the at least two components are each in a range of about 60° to about 90°.

14. The method of claim 12 wherein the deposition angles of the at least two components are each in a range of about 75° to about 90°.

15. The method of claim 12 wherein the at least two components are each deposited at substantially equal deposition rates.

16. The method of claim 12 wherein the at least two components are each deposited at unequal deposition rates.

17. The method of claim 12 wherein the at least two components are characterized by an inability to spontaneously self-assemble with each other.

18. A method for growing a thin film structure upon a substantially planar substrate, the method comprising:
depositing a first component from a first deposition direction at a first deposition angle; and
simultaneously depositing a second component from a second deposition direction different than the first deposition direction at a second deposition angle, wherein the first and second deposition directions are measured in a plane of the thin film structure and the first and second deposition angles are measured with respect to a line perpendicular to the plane of the thin film structure.

19. The method of claim 18 and further comprising:
orienting the first and second deposition angles and the first and second deposition directions to impart lateral composition modulations in the thin film structure.

20. The method of claim 18 and further comprising:
orienting the first and second deposition angles and the first and second deposition directions to cause a top surface of the thin film structure as it is grown to have an uneven film topography comprising mounds and valleys, wherein different sides of the mounds tend to collect more atoms of one of the first and second components during simultaneous deposition of the first and second components.

21. The method of claim 18 wherein the first and second deposition angles are each in a range of about 60° to about 90°.

22. The method of claim 18 wherein the first and second deposition angles are each in a range of about 75° to about 90°.

23. The method of claim 18 wherein the first and second components are deposited at substantially equal deposition rates.

24. The method of claim 18 wherein the first and second components are deposited at unequal deposition rates.

25. The method of claim 18 wherein the first and second components are characterized by an inability to spontaneously self-assemble with each other.
